(19) United States
(12) Patent Application Publication
(10) Pub. No.: US 2026/0290473 A1
(43) Pub. Date: Sep. 24, 2026

(54) VOLTAGE SELECTION FOR MEMORY SYSTEMS

(71) Applicant: Micron Technology, Inc., Boise, ID (US)

(72) Inventors: Liang Yu, Boise, ID (US); Jonathan S. Parry, Boise, ID (US); Dustin L. Holloway, Meridian, ID (US)

(21) Appl. No.: 19/559,723

(22) Filed: Mar. 6, 2026

Related U.S. Application Data
(60) Provisional application No. 63/773,953, filed on Mar. 18, 2025.

(51) Int. Cl. G11C 16/30; G11C 16/26

(52) U.S. Cl. CPC G11C 16/30; G11C 16/26

(57) ABSTRACT

Methods, systems, and devices for voltage selection for memory systems are described. A memory system may include a first interface including a first power supply and a second power supply input providing power to one or more memory devices at a first and second voltage level, and a third power supply input providing power to a controller of the memory system at a third voltage level. The memory system may further include a second interface coupled with a corresponding interface of a host system. The second interface may include circuitry configuring one or more pins to output a fixed combination of signals indicating a set of voltage levels, or the controller of the memory system may configure the one or more pins to output a selected combination of signals. The set of voltage levels may include settings for the first, second, and third voltage levels.

### CROSS REFERENCE

The present application for patent claims priority to U.S. Patent Application No. 63/773,953 by Yu et al., entitled “VOLTAGE SELECTION FOR MEMORY SYSTEMS,” filed Mar. 18, 2025, which is assigned to the assignee hereof, and which is expressly incorporated by reference in its entirety herein.

### TECHNICAL FIELD

The following relates to one or more systems for memory, including voltage selection for memory systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not- or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports voltage selection for memory systems in accordance with examples as disclosed herein.

FIG. 2 shows an example of a system that supports voltage selection for memory systems in accordance with examples as disclosed herein.

FIG. 3 shows an example of a system that supports voltage selection for memory systems in accordance with examples as disclosed herein.

FIG. 4 shows an example of a system that supports voltage selection for memory systems in accordance with examples as disclosed herein.

FIG. 5 shows an example of a system that supports voltage selection for memory systems in accordance with examples as disclosed herein.

### DETAILED DESCRIPTION

In some examples, a memory system may be coupled with a host system (e.g., a system on a chip (SoC)) as well as a power supply. In some cases, the power supply may be an example of a power management integrated circuit (PMIC) that may be coupled with, or included in, the host system. The host system and the power supply may support various functions of the memory system, one of which may include supplying power to the memory system. For example, the memory system may include a first interface with one or more power supply inputs coupled with the power supply, including a first power supply input (e.g., Vcc) and a second power supply input (e.g., Vccq). In some cases, the first power supply input may have a first voltage level (e.g., 2.5 Volts (V)) and may supply power to one or more memory devices of the memory system, while the second power input may have a second voltage level (e.g., 1.2 V) and may supply power to a controller (e.g., an application specific integrated circuit (ASIC)) of the memory system as well as the one or more memory devices. Some memory systems may include a regulator, such as a low-dropout (LDO) regulator coupled with the second power supply input to power one or more components of the controller (e.g., logic circuitry, a core) at a third, lower voltage level (e.g., below 1.2 V). Using a lower voltage to power the one or more components of the controller may reduce power consumption and thermal load. For example, improvements in controller design and process nodes having smaller feature sizes may reduce operating voltage for the circuit components (e.g., transistors), which may reduce power consumption. Other systems, in place of the regulator, may include a third power supply input (e.g., Vccq2, VccqX), which may be coupled with the controller and may be configured to power the one or more components at the third voltage However, the host system may lack functionality for determining different supported voltages for the controller or other components (e.g., for power rail design) of the memory system, and so a new design for voltage selection may be desirable to improve a flexibility and compatibility of memory systems as well as to enable further power reduction.

As described herein, the memory system may be configured to support voltage selection for various power supply inputs. For example, the memory system may include a second interface coupled with a corresponding interface of the host system, where the second interface may include one or more pins that may be configured to output a combination of signals (e.g., a fixed combination) indicating a set of voltage levels, the set including settings for the first voltage level, the second voltage level, and the third voltage level. The host system may be operable to output an indication of the set of voltage levels to the power supply (e.g., PMIC) via another interface of the host system, where the power supply may provide the corresponding voltage levels for each of the power supply inputs accordingly. Some memory systems may include fixed circuitry coupled with the one or more pins of the memory system (e.g., using pull-down, pull-up, or voltage division circuitry, among other circuitry) to configure the one or more pins to output a fixed combination of signals. Additionally, or alternatively, some memory systems may include circuitry to enable a controller of the memory system to configure the one or more pins to output a selected combination of signals. Further, in some cases, the memory system may be configured to couple one or more components with a voltage regulator for a first time period and to couple the one or more components with the third power supply input for a second time period.

As opposed to other different methods involving fixed voltages for a power supply, the techniques described herein may enable improved compatibility between devices. For example, configuring one or more pins using fixed circuitry or configurable pin circuitry (e.g., during manufacture, before or at a start of operation) may enable the host system to determine supported voltages for various components of the memory system regardless of differences or changes between the host system and the memory system by using provided pin bias, enabling custom voltage level configuration. Configuring pins to output a combination of signals indicating voltage levels may enable lower supported voltage operation than one or more default voltages at a host system, reducing power consumption, as well as may prevent damage to one or more components (e.g., indicating supported voltages may prevent utilization of voltages above a threshold), as well as may prevent other incompatibilities between devices (e.g., indicating supported voltages may prevent using a voltage below a minimum threshold). Enabling configuration of the one or more pins may further provide custom system design for desired use, increasing efficiency and improving an overall system flexibility, while configurable pins may reduce waste associated with additional manufacturing.

In addition to applicability in memory systems as described herein, techniques for selecting voltages in memory systems may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by enabling increased compatibility between devices as well as decreased power consumption, which may extend the life and use of electronic devices, thereby reducing electronic waste, among other benefits. Features of the disclosure are illustrated and described in the context of systems, devices, and circuits.

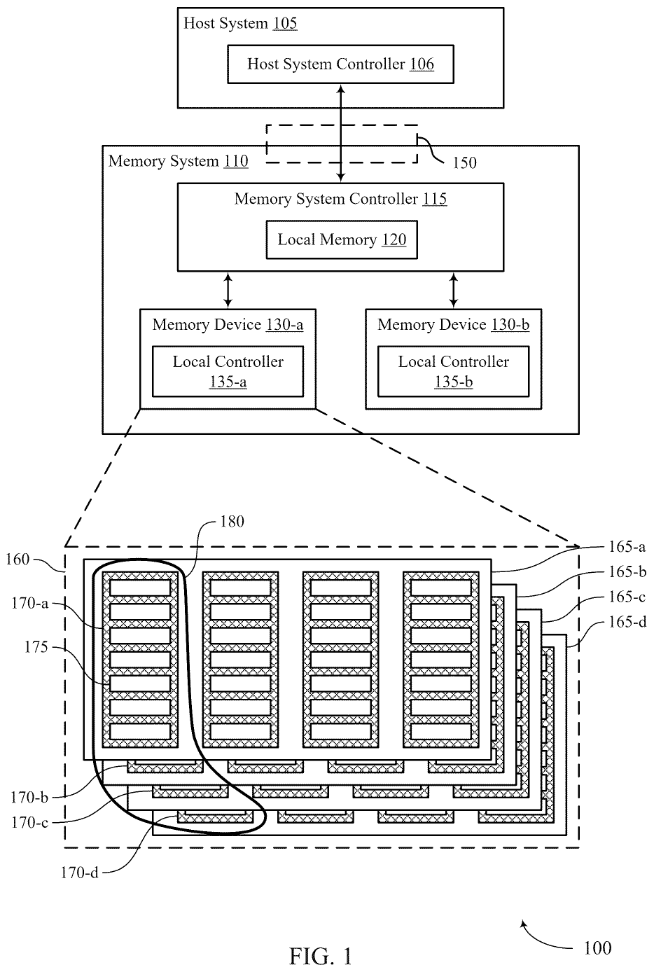

FIG. 1 shows an example of a system 100 that supports voltage selection for memory systems in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations-which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some examples, the memory system 110 may support a core voltage for one or more controllers (e.g., for the memory system controller 115, for an ASIC) in accordance with one or more process nodes. As one or more processes or designs in controllers improves, a controller core voltage may be reduced. However, it may be difficult for a host system, such as the host system 105 (e.g., a mobile host system, an automobile host system) to determine a supported power voltage for power rail design at the memory system 110.

As described herein, the memory system 110 may be configured to support voltage selection for various voltage sources and power rails. For example, the memory system 110 may include a first interface coupled with a power supply (e.g., a PMIC) and including one or more power supply inputs. The memory system 110 may also include a second interface, such as an interface 150, coupled with a corresponding interface of the host system 105, where the interface 150 may include one or more pins (e.g., power ID pins) that may be configured to output a combination of signals (e.g., a fixed combination) indicating a set of voltage levels. The set of voltage levels may include settings for a first voltage level, a second voltage level, and a third voltage level for the one or more power supply inputs. The host system 105 (e.g., via the host system controller 106) may be operable to output an indication of the set of voltage levels to a power supply (e.g., a PMIC) via another interface of the host system 105, where the power supply may provide the corresponding voltage levels for each of the power supply inputs accordingly. In some examples, the memory system 110 may include fixed circuitry coupled with the one or more pins (e.g., using pull-down, pull-up, or voltage division circuitry, among other circuitry). Additionally, or alternatively, the memory system 110 may include circuitry to enable a controller of the memory system (e.g., the memory system controller 115, one or more local controllers 135) to configure the one or more pins to output a selected combination of signals.

Using the one or more pins to indicate supported voltages as described herein (e.g., using a power ID pin design in UFS package or ASIC design) may enable improved compatibility between components of the memory system 110 and the host system 105, as well as improve overall flexibility of the system 100. For example, utilizing one or more pins may enable one or more UFS devices, such as the memory system 110, to request selected or configured power rail voltages from the host system 105 regardless of differences in ASIC processes or NAND datapath processes. The pins may also enable the host system 105 to configure different power rail voltages to the one or more UFS devices, where the host system controller 106 (e.g., an SoC) may sense the UFS provided pin bias and provide the corresponding power (e.g., via a PMIC).

The system 100 may include any quantity of non-transitory computer readable media that support voltage selection for memory systems. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

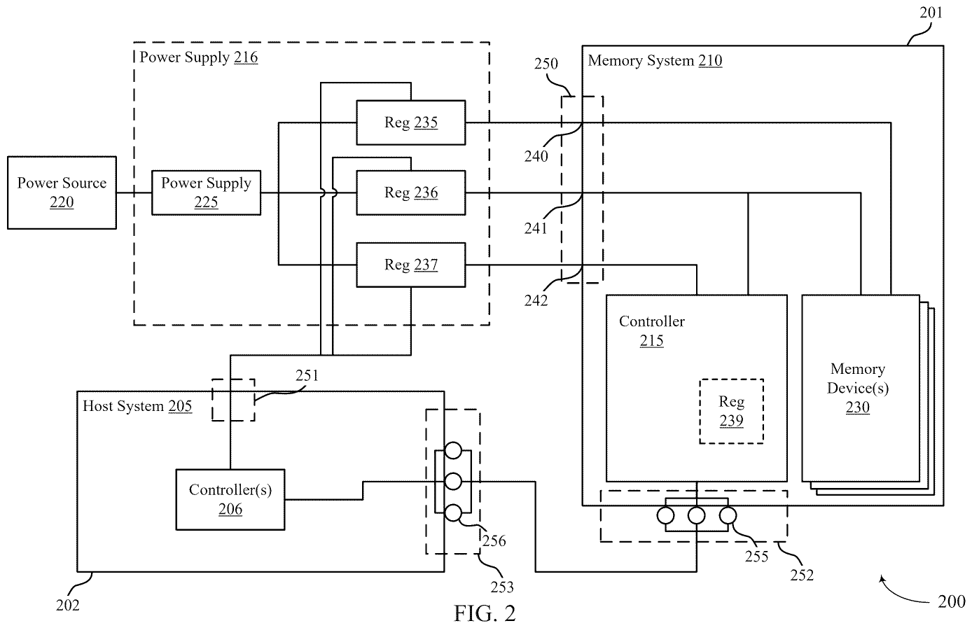

FIG. 2 shows an example of a system 200 that supports voltage selection for memory systems in accordance with examples as disclosed herein. In some examples, the system 200 may support aspects of the system 100. For example, the system 200 may include a host system 205, a memory system 210, one or more memory devices 230, a controller 215, and one or more controllers 206, which may be examples of a host system 105, a memory system 110, one or more memory devices 130, one or more memory system controllers 115 (or local controllers 135), and one or more host system controllers 106 as described with reference to FIG. 1, respectively. In some examples, the memory system 210 may support voltage selection for one or more power supply inputs as described herein.

For example, a power supply 216 may power one or more components of the memory system 210 (e.g., a memory module including an ASIC and NAND memory) via one or more power supply inputs. As shown in FIG. 2, the memory system 210 may include an interface 250 of a substrate 201 (e.g., a physical substrate to which one or more components of the memory system 210, such as the controller 215, are attached, mounted, or formed, a printed circuit board (PCB)) of the memory system 210, where the interface 250 may be coupled with the power supply 216 (e.g., a PMIC). The power supply 216 may in some cases include a single power supply, or multiple power supplies. For example, the power supply 216 may be coupled with a power source 220 (e.g., a power source, a battery). The power supply 216 may also include a regulator 235 (e.g., an LDO regulator), a regulator 236, and a regulator 237. In some examples, the power supply 216 may further include an individual power supply 225 that may be coupled with the power source 220 and with one or more of the regulators 235, 236 and 237. Additionally, or alternatively, one or more of the regulators 235, 236, and 237 may be coupled directly with the power source 220, or multiple power supplies 225 may be included in the power supply 216 (e.g., individual power supplies for respective regulators). In some cases, the power supply 225 may be an example of a switched mode power supply (SMPS). In some examples, a voltage level of the power source 220 may be a DC voltage that is higher than voltages used for the memory system 210 (e.g., the voltage level of the power source may be in the range of 3 V to 5 V). The power supply 216 may be coupled with the host system 205 via one or more interfaces, such as via an interface 251 of the host system 205, or may be included in the host system 205, for example, attached to a same substrate 202 of the host system 105 to which the one or more controllers 206 may be attached.

In some examples, the interface 250 of the memory system 210 may include a first power supply input 240, a second power supply input 241, and a third power supply input 242, where each power supply input may be coupled with the power supply 216. For example, the regulator 235 may be coupled with the first power supply input 240 (e.g., a first power supply input coupled with a first voltage source, such as a first power rail), and may be configured to regulate a voltage supplied to the first power supply input 240 of the memory system 210 such that the voltage is equal to a first voltage level (e.g., 2.5 V). The regulator 236 may be coupled with the second power supply input 241 (e.g., a second power supply input coupled with a second voltage source, such as with a second power rail), and may be configured to regulate a voltage supplied to the second power supply input 241 such that the voltage is equal to a second voltage level (e.g., 1.2 V). The regulator 237 may be coupled with the third power supply input 242 (e.g., a third power supply input coupled with a third voltage source, such as with a third power rail), and may be configured to regulate a voltage supplied to the third power supply input 242 such that the voltage is equal to a third voltage level (e.g., at or between 0.6 V and 1.0 V).

In some examples, the first power supply input 240 may be coupled with the one or more memory devices 230 (e.g., one or more memory devices mounted to the substrate 201) and may be configured to power one or more first components (e.g., may power array circuitry, such as for programming, erasing, or biasing components of one or more arrays) of the one or more memory devices 230 at the first voltage level. The second power supply input 241 may be coupled with the one or more memory devices 230, but may be configured to power one or more second components of the one or more memory devices 230 at the second voltage level (e.g., may power input/output for communication between the controller 215 and the one or more memory devices 230). Further, the power supply input 241 may in some cases power one or more components of the controller 215 at the second voltage level. The third power supply input 242 may be coupled with the controller 215 (e.g., a controller mounted to the substrate 201) and may be configured to power one or more components of the controller 215 at the third voltage level. For example, the third power supply input 242 may power a core of the controller 215 (e.g., provide Vccq2, provide Vccq_core to provide a lower voltage to a UFS ASIC core) Optionally, the third power supply input 242 may also power other low voltage domains of the controller 215 or the memory device 230, such as a physical layer, low density parity check (LDPC), ODT, etc.

In some examples, the controller 215 may include one or more regulators, such as a regulator 239 (e.g., an LDO regulator), which may be coupled with the third power supply input 242 (or the second power supply input 241). The regulator 239 may lower an initial voltage of the third power supply input 242 (e.g., to lower Vccq2=1.0 V to a lower voltage). In some cases, the regulator 239 may be coupled with the core of the controller 215 and may be configured to regulate a voltage supplied to the core (e.g., may reduce 1.0 V to 0.75 V). In another example, if the core is powered by the power supply input 241 (e.g., Vccq), the power supply input 241 may be coupled with the regulator 239 to lower a voltage supplied to the core. In yet another example, the memory system 210 may include one or more power supplies or regulators coupled with one or more of the first power supply input 240, the second power supply input 241, or the third power supply input 242.

In some examples, the memory system 210 may include an interface 252 (e.g., a second interface) including a quantity of pins (e.g., a set of one or more pins). For example, the interface 252 may include a quantity of pins 255 that may be configured to be coupled with a corresponding interface 253 of the host system 205, where the interface 253 may include one or more corresponding pins 256. The pins and interfaces may enable communication between the controller 215 and one or more components of the memory system 210 with the one or more controllers 206 and one or more components of the host system 205. For example, the interface 252 and the interface 253 and associated pins may exchange M-PHY signaling. In some cases, the quantity of pins 255 may include one or more solder balls (e.g., one or more balls reserved for use, or repurposed for indicating voltage levels). Further, the quantity of pins 255 may be referred to as power identifier/identification (PID) pins.

In some examples, the quantity of pins 255 may be configured to output a combination of signals indicating a set of voltage levels of a set of multiple sets of voltage levels. For example, the memory system 210 may include fixed circuitry that may configure the pins (e.g., the circuitry may bias the pins statically) to output a fixed combination of signals. Additionally, or alternatively, the controller 215 may configure the quantity of pins 255 to output a selected combination of signals. In some examples, each of set of multiple sets of voltage levels may include settings for the first voltage level, the second voltage level, and the third voltage level, enabling the memory system 210 to notify the host system 205 to use a fixed or selected set of voltage levels (e.g., to use Vccq2/Vccq_core at a voltage between 0.6V to 1.0V).

In some examples, the host system 205 (e.g., a mobile host system, an automobile host system) may sense (e.g., detect) the combination of signals provided by the quantity of pins 255, and may configure the power supply 216 (e.g., PMIC) to provide corresponding voltages according to the set of voltages via the interface 251. For example, the host system 205 may transmit control signaling to the power supply 216, which may control an output of the regulators 235, 236, and 237 or at one or more other components to provide different values for the first voltage, the second voltage, and the third voltage.

In some examples, utilizing the quantity of pins 255 (e.g., with fixed circuitry, configured by the controller 215) may enable the memory system 210 (e.g., an mNAND package and ASIC) to have a capability for controller core voltage selection in one or more systems, which may improve compatibility between the memory system 210 and other devices. For example, configuring the pins may enable the host system 205 to sense (e.g., detect, request and receive) supported voltages indicated by the memory system 210, which may enable additional compatibility between devices regardless of voltage support, as well as reduce a likelihood of damaging components by using unsupported voltages. Further, configuring the pins may improve compatibility with changes in memory system design and NAND datapath processes, as well as enable a more flexible configuration for a system for different use cases.

Further, communicating using the pins may enable usage of the third power supply input 242, which may allow the memory system 210 to reduce voltage and power consumption by implementing a lower configured voltage for powering a controller 215 core. For example, the third voltage level may be equal to or within a threshold value of a voltage level used by the controller 215 to power the core or the second data path, resulting in less current being pulled by regulators (e.g., the regulator 239) of the controller 215. This may effectively lower the overall power consumption of the memory system 210 and system 200. Further, doing so may reduce a thermal load on the memory system 210 due to less power being drawn.

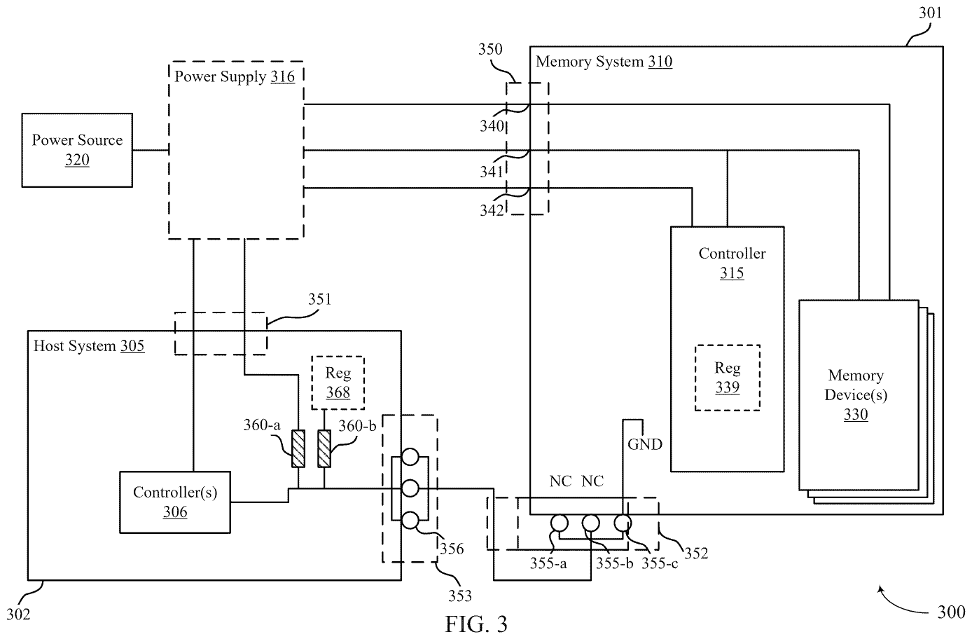

FIG. 3 shows an example of a system 300 that supports voltage selection for memory systems in accordance with examples as disclosed herein. In some examples, the system 300 may support aspects of the system 100 and the system 200. For example, the system 300 may include a host system 305, a memory system 310, one or more memory devices 330, and one or more controllers 315 which may be examples of a host system 105, a memory system 110, one or more memory device 130, and one or more memory system controllers 115 as described with reference to FIG. 1, respectively. In some examples, the memory system 310 may support circuitry involving controller bias or power supply bias for outputting a fixed combination of signals indicating voltage levels.

As described herein, the memory system 310 may include a first interface 350 of a substrate 301 and a second interface 352 of the substrate 301, where the first interface 350 may include a first power supply input 340 (e.g., Vcc), a second power supply input 341 (e.g., Vccq), and a third power supply input 342 (e.g., Vccq2) coupled with a power supply 316, and the second interface 352 may include a quantity of pins 355 configured to be coupled with a corresponding interface 353 (and corresponding pins 356) of a substrate 302 of the host system 305. The power supply 316 may include a power source 320 (e.g., a power source, a battery) and one or more regulators or power supplies for coupling with and providing power to the power supply inputs corresponding to a first voltage, a second voltage, and a third voltage, respectively. In some cases, the power supply 316 may be coupled with the host system 305 via one or more interfaces, such as via an interface 351 of the host system 305, or may be included in the host system 305. The first power supply input 340 and the second power supply input 341 may be coupled with one or more memory devices 330 of the memory system 110 and provide power for one or more first components and one or more second components of the one or more memory devices 330 at a first voltage level and a second voltage level, respectively. The third power supply input 342 may be coupled with the controller 315 and may provide power for one or more components of the controller at a third voltage level. The controller 315 may also include a voltage regulator 339 (e.g., a core voltage regulator).

In some examples, the quantity of pins 355 may be configured (e.g., by circuitry or physical setup of the pins) to output a fixed combination of signals indicating a set of voltage levels of a set of multiple sets of voltage levels. For example, one or more pins of the quantity of pins 355, including a pin 355-a and a pin 355-b, may be decoupled from the first power supply input 340, the second power supply input 341, the third power supply input 342, and a ground, and may output a first signal (e.g., a logical value ‘1’) for the fixed combination of signals in accordance with being decoupled. In such a case, the one or more pins may be considered as “Not Connected” (NC). Additionally, or alternatively, one or more pins of the quantity of pins 355, such as a pin 355-c, may be coupled with ground (e.g., GND), and may output a second signal (e.g., a logical value ‘0’) for the fixed combination of signals in accordance with being coupled with ground. In some cases, the quantity of pins 355 and signals may be three (e.g., power ID pins output a bit signal vector [2:0]). In some cases, the fixed combination may indicate a respective fixed combination of signals, where a state (e.g., GND, NC, a logical value ‘1’, a logical value ‘0’) of each pin 355 may be configured (e.g., at manufacture or before operation) and fixed by circuitry of the memory system 210. Additionally, or alternatively, other quantities of pins or pin states may be considered.

In some cases, the one or more controllers 306 of the host system 305 may be configured to receive the combination of signals indicating the fixed set of voltage levels via the quantity of pins 356. For example, the quantity of pins 356 may include a corresponding pin 356 for each of the pins 355-a, 355-b, and 355-c each indicating a respective signal (e.g., NC, NC, and GND, respectively, or any combination). The fixed combination of signals may indicate the configured set of voltage levels, where the one or more controllers 306 may be operable to output an indication of the set of voltage levels to the power supply 316 via the interface 351, where each of the set of multiple sets of voltage levels may include settings for the first voltage level, the second voltage level, and the third voltage level. In some cases, the one or more controllers 306 may be operable to receive the combination of signals in accordance with monitoring the quantity of pins 356 (corresponding to the quantity of pins 355) during a first duration, and to output the indication of the set of voltage levels during a second duration.

In some examples, the host system 305 may provide a controller bias or a power supply bias to the received signals. For example, the host system 305 may include one or more resistors 360 coupled with one or more pins 356 of the quantity of pins 356. In some examples, the one or more resistors 360, including a resistor 360-a, may be coupled with a power supply input of the interface 351 (e.g., Vcc, Vccq, PMIC bias). Additionally, or alternatively, one or more resistors 360, including a resistor 360-b, may be coupled with a voltage regulator of the host system 305, such as a regulator 368 (e.g., a voltage regulator for an internal power supply for the one or more controllers 306, SoC power, SoC bias). In some examples, the one or more controllers 306 may be operable to determine (e.g., using logic at the host system 305) the set of voltage levels of the set of multiple sets of voltage levels in response to the combination of signals, and may indicate the set of voltage levels. Additionally, or alternatively, the one or more controllers 306 may forward the same signals received at the pins 356. In some examples, the one or more resistors 360 may act as pull-up circuitry, or pull-down circuitry, for interpreting a state of each pin 356 and 355 (e.g., as NC or GND, as a logical value ‘1’ or a logical value ‘0’).

The fixed combination of signals and the indication may in some cases indicate an updated setting for a voltage level of the set of voltage levels. For example, one or more exemplary fixed signal combinations indicating respective sets of voltage levels may be illustrated in Table 1.

TABLE 1

| Vcc | Vccq | Vccq2 | | | |
|---|---|---|---|---|---|
| (V) | (V) | (V) | PWR_ID0 | PWR_ID1 | PWR_ID2 |
| 2.5 | 1.2 | 0.80 | GND | GND | GND |
| 2.5 | 1.2 | 0.80 | NC | NC | NC |
| 2.5 | 1.2 | 1.00 | NC | GND | NC |
| 2.5 | 1.2 | 0.80 | NC | GND | GND |
| 2.5 | 1.2 | 0.75 | GND | NC | NC |
| 2.5 | 1.2 | 0.70 | GND | NC | GND |
| 2.5 | 1.2 | 0.65 | NC | NC | GND |
| 2.5 | 1.2 | 0.60 | GND | GND | NC |

In the examples of Table 1, the host system 305 may utilize a combination of three signals (for three pins 355 and corresponding pins 356) to determine supported UFS voltages for each of the first power supply input 340, the second power supply input 341, and the third power supply input 342 (e.g., Vcc, Vccq, and a third voltage). The power IDs PWR_ID0, PWR_ID1, and PWR_ID2 may represent signals corresponding to the pins 355-a, 355-b, and 355-c. For example, as illustrated in FIG. 3, the pins 355 may output signals of NC, NC, and GND (e.g., bit values of ‘1’, ‘1’, and ‘0’ for a bit signal [2:0]), which may correspond to an updated voltage setting for the third power supply input 342 as 0.65 V. Additionally, or alternatively, other combinations according to Table 1 may be considered. Further, while Table 1 may illustrate indicating an updated setting for the third voltage level, other examples may involve the first and second voltage levels being updated, and other combinations of signals and voltage levels for each of the power supply inputs may be considered. In some cases, the third voltage level is less than the first voltage level and the second voltage level. Further, while Table 1 may illustrate three signals (e.g., for three bits), other quantity of bits may be considered (e.g., four or more bits ID if there is Vccq support for 1.0 V or lower, or for other power supply input or power rail combinations).

In some cases, the host system 305 may configure the voltage settings in accordance with outputting the indication of the set of voltage levels to the power supply 316. For example, the first voltage, the second voltage, and the third voltage may be updated according to the updated voltages in Table 1, or according to other examples. In some examples, utilizing a fixed combination of signals in accordance with fixed NC or GND states of one or more pins 355 may enable custom configuration of various operating voltages of the memory system 210 without added circuitry (e.g., by reusing one or more pins and regulators).

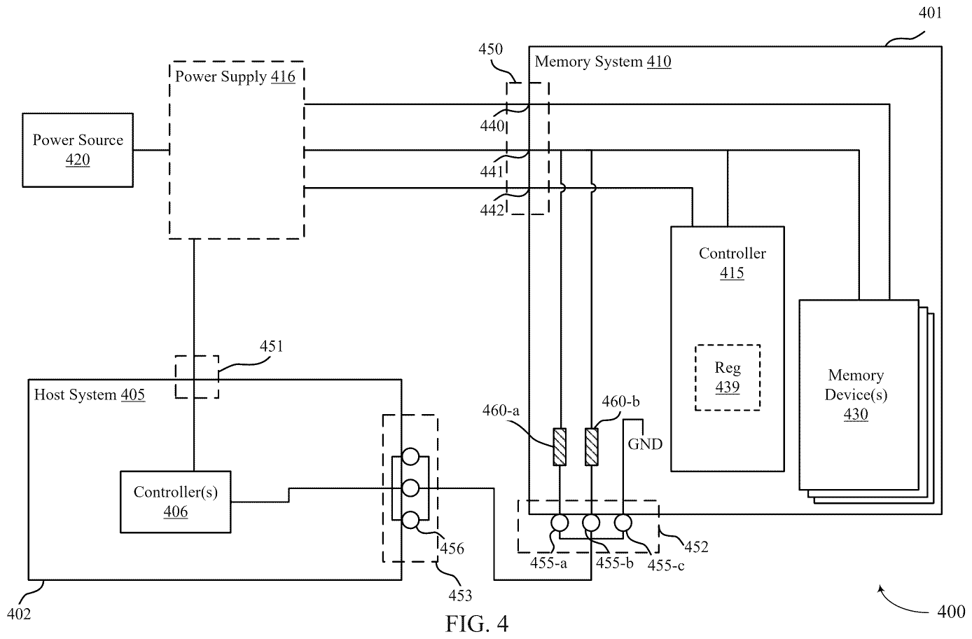

FIG. 4 shows an example of a system 400 that supports voltage selection for memory systems in accordance with examples as disclosed herein. In some examples, the system 400 may support aspects of the system 100, the system 200, and the system 300. For example, the system 400 may include a host system 405, a memory system 410, one or more memory devices 430, and one or more controllers 415 which may be examples of a host system 105, a memory system 110, one or more memory device 130, and one or more memory system controllers 115 as described with reference to FIG. 1, respectively. In some examples, the memory system 410 may support fixed bonding circuitry for outputting a fixed combination of signals indicating voltage levels.

As described herein, the memory system 410 may include a first interface 450 of a substrate 401 and a second interface 452 of the substrate 401, where the first interface 450 may include a first power supply input 440, a second power supply input 441, and a third power supply input 442 coupled with a power supply 416, and the second interface 452 may include a quantity of pins 455 configured to be coupled with a corresponding interface 453 (and corresponding pins 456) of a substrate 402 of the host system 405. The power supply 416 may include a power source 420 (e.g., a power source, a battery) and one or more regulators or power supplies for coupling with and providing power to the power supply inputs 440, 441, and 442 corresponding to a first voltage, a second voltage, and a third voltage, respectively. In some cases, the power supply 416 may be coupled with the host system 405 via one or more interfaces, such as via an interface 451 of the host system 405, or may be included in the host system 405. The first power supply input 440 and the second power supply input 441 may be coupled with one or more memory devices 430 of the memory system 410 and provide power for one or more first components and one or more second components of the one or more memory devices 430 at a first voltage level and a second voltage level, respectively. The third power supply input 442 may be coupled with the controller 315 and may provide power for one or more components of the controller at a third voltage level. The controller 415 may also include a voltage regulator 439 (e.g., a core voltage regulator).

In some examples, the quantity of pins 355 may be configured (e.g., by circuitry associated with the pins) to output a fixed combination of signals indicating a set of voltage levels of a set of multiple sets of voltage levels. For example, the system 400 may illustrate a system similar to that of system 300, but may include one or more resistors 460 in a fixed bonding configuration within the memory system 410 or substrate 401 (e.g., fixed bonded resistors in UFS package or substrate). For example, the memory system 410 may include one or more resistors 460 that may be coupled with one or more pins 455 of the quantity of pins 455. In some cases, the one or more resistors 460 may be coupled with the second power supply input 441 as illustrated. Additionally, or alternatively, the one or more resistors 460 may be coupled with the first power supply input 440 or with the voltage regulator 439 or another voltage regulator and power supply. In some cases, the pins 455 may output a signal for the fixed combination of signals in accordance with being coupled with the one or more resistors 460. For example, pins 455-a and 455-b may output a same signal for a state associated with coupling of resistors 460-a and 460-b (e.g., a logical value ‘1’ when coupled with a power supply such as the second power supply input 441), while the pin 455-c may output a different state (e.g., a logical value ‘0’) associated with being coupled with ground (e.g., GND). Further, different resistors may be implemented to indicate each state, or to indicate more than two states. In some cases, the one or more resistors 460 may be configured as pull-up circuits, as pull-down circuits, or as voltage divider circuits. For example, the one or more resistors 460 may pull up a voltage to Vcc or to Vccq to indicate one of the states, or a voltage may be lowered using a resistor division network.

In some cases, the one or more controllers 406 of the host system 405 may be configured to receive the fixed combination of signals indicating the fixed set of voltage levels via the quantity of pins 456, and may be operable to output an indication of the set of voltage levels to the power supply 416 via the interface 451. For example, the host system 405 may interpret the combination of signals received at the quantity of pins 456 using Table 1 (or a similar table) to determine the set of voltage levels (e.g., settings for Vcc, Vccq, and Vccq2) and may indicate the set of voltage levels to the power supply 416. In some examples, utilizing fixed bonded circuitry to output a fixed combination of signals may enable custom configuration of various operating voltages of the memory system 210 with additional configurability in design by designing or selecting one or more resistors (e.g., in manufacture).

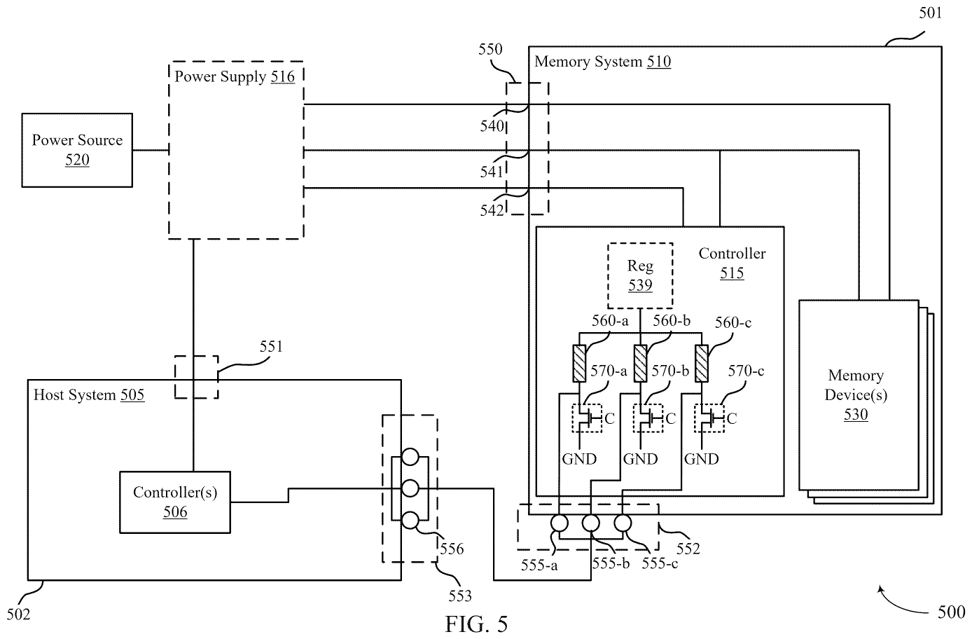

FIG. 5 shows an example of a system 500 that supports voltage selection for memory systems in accordance with examples as disclosed herein. For example, the system 300 may include a host system 505, a memory system 510, one or more memory devices 530, and one or more controllers 515 which may be examples of a host system 105, a memory system 110, one or more memory device 130, and one or more memory system controllers 115 as described with reference to FIG. 1, respectively. In some examples, the memory system 510 may support a controller configuring one or more pins (e.g., using static pin configurations) to output selected voltages for one or more power supply inputs.

As described herein, the memory system 510 may include a first interface 550 of a substrate 501 and a second interface 552 of the substrate 501, where the first interface 550 may include a first power supply input 540, a second power supply input 541, and a third power supply input 542 coupled with a power supply 516, and the second interface 552 may include a quantity of pins 555 configured to be coupled with a corresponding interface 553 (and corresponding pins 556) of a substrate 502 of the host system 505. The power supply 516 may include a power source 520 (e.g., a power source, a battery) and one or more regulators or power supplies for coupling with and providing power to the power supply inputs 540, 541, and 542 corresponding to a first voltage, a second voltage, and a third voltage, respectively. In some cases, the power supply 516 may be coupled with the host system 505 via one or more interfaces, such as via an interface 551 of the host system 505, or may be included in the host system 505. The first power supply input 540 and the second power supply input 541 may be coupled with one or more memory devices 530 of the memory system 110 and provide power for one or more first components and one or more second components of the one or more memory devices 530 at a first voltage level and a second voltage level, respectively. The third power supply input 542 may be coupled with the controller 515 and may provide power for one or more components of the controller at a third voltage level.

In some examples, the controller 515 may be operable to configure the quantity of pins 555 to output a selected combination of signals indicating a set of voltage levels of a set of multiple sets of voltage levels. For example, the memory system 510 may include a set of multiple switches 570 of the controller 515 that may be coupled with the quantity of pins 555. For example, the controller 515 may include a switch 570-a, a switch 570-b, and a switch 570-c coupled with pins 555-a, 555-b, and 555-c, respectively. In some cases, each switch 570 may be an example of a transistor or other switching element. Additionally, or alternatively, the memory system 110 may include one or more resistors 560 of the controller 515 that may be coupled with one or more pins 555 of the quantity of pins 555, such as resistors 560-a, 560-b, and 560-c.

The one or more resistors 560 and/or the one or more switches 570 may be coupled with an internal pull-up (or pull-down) power supply (e.g., pull up/pull down or complementary metal-oxide semiconductor (CMOS) circuits to generate a PID[2:0] bias). For example, the one or more resistors 560 may be coupled with an internal power supply, such as the regulator 539, or another regulator. In some cases, the internal power supply be lowered by implementing a resistor division network using the resistors 560. In some examples, a pull-up (or pull-down) main power supply may originate from the second power supply input 541 (e.g., Vccq) or may originate from a regulator if only the third voltage (e.g., Vccq2 for the third power supply input 542) is to be configured. For example, the regulator may be an “always on” (Aon) LDO regulator (e.g., which receives power while the PMIC is outputting power), and may lower Vccq from 1.2 V to 0.8 V, where the 0.8 V may be supplied for a main pull-up or pull-down power supply. Additionally, or alternatively, if a second voltage setting (e.g., Vccq for the power supply input 541) of 1.0 V is to be configured, the main pull-up (or pull-down) power supply may originate from the first voltage and the first voltage supply input 540 (e.g., Vcc). Additionally, or alternatively, the resistors 560, the switches 570, or the pins 555 may be coupled with other examples of power supply inputs or regulators.

In some examples, the controller 515 may be operable to configure each pin 555 of the quantity of pins 555 to output a first signal (e.g., a logical value ‘1’ or a logical value ‘0’) or a second signal (e.g., the other of the logical value ‘1’ or the logical value ‘0’) for the selected combination of signals in accordance with switching a respective switch 570 of the set of multiple switches 570. For example, (e.g., during manufacture or before operation), the controller 515 may configure the pins 555 to output a selected configuration of signals (e.g., from Table 1 or other examples of signals) to indicate selected voltages for the third power supply input 542, as well as for the first power supply input 540 and the second power supply input 541. In some cases, the controller 515 may output a control signal that may be received by each switch 570 controlled by the controller 515. For example, a control signal (e.g., including a bit signal [2:0]) may set each of the pins to output a corresponding bit signal (e.g., the same bit signal [2:0]). The control signal may originate from circuits under (e.g., powered by) the first voltage, the second voltage, or another voltage (e.g., under main Vcc, Vccq or Aon domains). For example, control signals (e.g., bits [2:0] information) may originate from an ASIC efuse read out (e.g., under an Aon regulator). Additionally, or alternatively, the controller 515 may include metal switches, or hardware logic for communicating control signals with the switches 570 (e.g., efuse, ROM). Further, the controller 515 may implement ASIC general-purpose input/output (GPIO) outputs for communicating control signals to the pins 555. In some examples, the state of the pins may be static (e.g., UFS ASIC static pin configuration). For example, the controller 515 may configure the pins at a time period outside of operation (e.g., power on reset).

In some examples, the memory system 510 may switch between voltage sources (e.g., using a handshake sequence). For example, the controller 515 may include a regulator configured to provide power for the one or more components of the controller 515 from the first power supply input 540 or the second power supply input 541. The controller may be operable to couple the one or more components with the regulator for a first time period. For example, an ASIC may have an LDO regulator (e.g., switched on/off (SoF) LDO regulator from 1.2 V to target 0.75 V)) internally. The controller 515 may (e.g., after a power up of Vcc or Vccq and associated power supply inputs) decouple the one or more components from the regulator for a second time period subsequent to the first time period and may couple the one or more components with the third power supply input. For example, the controller 515 may read control signal information (e.g., from firmware image or NAND, or ASIC efuse, among other examples) and may output a control signal (e.g., output PID [2:0]) to configure the pins 555 to output a signal to adjust the third voltage (e.g., to adjust the SOC/PMIC's Vccq2 power rail). After outputting the signal, the ASIC may switch one or more components from the regulator (e.g., the internal SoF LDO regulator) to a direct power supply from the third power supply input 542 (e.g., a direct supply of Vccq2). Additionally, or alternatively, the controller 515 may switch the one or more components to another direct or indirect power source. In some cases, the regulator may be switched off after switching to the direct power supply. Additionally, or alternatively, although switching one or more components from the regulator to the third power supply input 542 is described with respect to FIG. 5, similar processes may be supported by the memory systems 210, 310, and 410 of FIGS. 2-4.

In some cases, the one or more controllers 506 of the host system 505 may be configured to receive the fixed combination of signals indicating the fixed set of voltage levels via the quantity of pins 556, and may be operable to output an indication of the set of voltage levels to the power supply 516 via the interface 551, where each of the set of multiple sets of voltage levels may include settings for the first voltage level, the second voltage level, and the third voltage level. Additionally, or alternatively, although not shown, other circuitry may be considered for outputting fixed combinations of signals. In some examples, the selected combination of signals may indicate an updated setting for the third voltage level, and/or the second and first voltage levels. In some examples, utilizing configurable pin circuitry to output selected combinations of signals and selected voltages may enable additional flexibility between use cases for one or more users (e.g., after manufacture and before operation).

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 1: A memory system, including: a controller mounted to a substrate; one or more memory devices mounted to the substrate and coupled with the controller; a first interface of the substrate including a first power supply input, a second power supply input, and a third power supply input, where the first power supply input and the second power supply input are coupled with the one or more memory devices and provide power for one or more first components and one or more second components of the one or more memory devices at a first voltage level and a second voltage level, respectively, and where the third power supply input is coupled with the controller and provides power for one or more components of the controller at a third voltage level; and a second interface of the substrate including a plurality of pins configured to be coupled with a corresponding interface of a host system, the plurality of pins configured to output a fixed combination of signals indicating a set of voltage levels of a plurality of sets of voltage levels, where each of the plurality of sets of voltage levels includes settings for the first voltage level, the second voltage level, and the third voltage level.
Aspect 2: The memory system of aspect 1, further including: one or more resistors coupled with one or more pins of the plurality of pins, where the one or more resistors are coupled with at least one of the first power supply input the second power supply input, or a voltage regulator of the controller.
Aspect 3: The memory system of aspect 2, where the one or more pins output a first signal for the fixed combination of signals in accordance with being coupled with the one or more resistors.
Aspect 4: The memory system of any of aspects 2 through 3, where the one or more resistors are configured as pull-up circuits, as pull-down circuits, or as voltage divider circuits.
Aspect 5: The memory system of any of aspects 1 through 4, where at least one pin of the plurality of pins is decoupled from the first power supply input, the second power supply input, the third power supply input, and a ground, the at least one pin outputs a first signal for the fixed combination of signals in accordance with being decoupled.
Aspect 6: The memory system of any of aspects 1 through 5, where at least one pin of the plurality of pins is coupled with ground, the at least one pin outputs a second signal for the fixed combination of signals in accordance with being coupled with ground.
Aspect 7: The memory system of any of aspects 1 through 6, where the fixed combination of signals indicates an updated setting for the third voltage level.
Aspect 8: The memory system of any of aspects 1 through 7, where the third voltage level is less than the first voltage level and the second voltage level.

An apparatus is described. The following provides an overview of aspects of the apparatus as described herein:
Aspect 9: A memory system, including: a controller mounted to a substrate; one or more memory devices mounted to the substrate and coupled with the controller; a first interface of the substrate including a first power supply input, a second power supply input, and a third power supply input, where the first power supply input and the second power supply input are coupled with the one or more memory devices and provide power for one or more first components and one or more second components of the one or more memory devices at a first voltage level and a second voltage level, respectively, and where the third power supply input is coupled with the controller and provides power for one or more components of the controller at a third voltage level; and a second interface of the substrate including a plurality of pins configured to be coupled with an interface of a host system and with the controller, the controller operable to configure the plurality of pins to output a selected combination of signals indicating a set of voltage levels of a plurality of sets of voltage levels, where each of the plurality of sets of voltage levels includes settings for the first voltage level, the second voltage level, and the third voltage level.
Aspect 10: The memory system of aspect 9, further including: a plurality of switches of the controller that are coupled with the plurality of pins, where the controller is operable to configure each pin of the plurality of pins to output a first signal or a second signal for the selected combination of signals in accordance with switching a respective switch of the plurality of switches.
Aspect 11: The memory system of any of aspects 9 through 10, further including: one or more resistors of the controller that are coupled with one or more pins of the plurality of pins, where the one or more resistors are coupled with a voltage regulator of the controller.
Aspect 12: The memory system of aspect 11, where the one or more resistors are configured as pull-up circuits, as pull-down circuits, or as voltage divider circuits.
Aspect 13: The memory system of any of aspects 9 through 12, further including: a voltage regulator of the controller that is configured to provide power for the one or more components of the controller from the first power supply input or the second power supply input, where the controller is operable to: couple the one or more components with the voltage regulator for a first time period; decouple the one or more components from the voltage regulator for a second time period subsequent to the first time period; and couple the one or more components with the third power supply input for the second time period.
Aspect 14: The memory system of any of aspects 9 through 13, where the selected combination of signals indicates an updated setting for the third voltage level.
Aspect 15: The memory system of any of aspects 9 through 14, where the third voltage level is less than the first voltage level and the second voltage level.

An apparatus is described. The following provides an overview of aspects of the apparatus as described herein:
Aspect 16: A host system, including: one or more controllers; a first interface coupled with a power supply and the one or more controllers; and a second interface including a plurality of pins coupled with an interface of a substrate of a memory system and with the one or more controllers, the one or more controllers configured to receive a combination of signals indicating a set of voltage levels of a plurality of sets of voltage levels via the plurality of pins, where the one or more controllers are operable to output an indication of the set of voltage levels to the power supply via the first interface, where each of the plurality of sets of voltage levels includes settings for a first voltage level, a second voltage level, and a third voltage level.
Aspect 17: The host system of aspect 16, further including: one or more resistors coupled with one or more pins of the plurality of pins, where the one or more resistors are coupled with a power supply input of the first interface or with a voltage regulator of the host system.
Aspect 18: The host system of any of aspects 16 through 17, where the one or more controllers are operable to determine the set of voltage levels of the plurality of sets of voltage levels in response to the combination of signals.
Aspect 19: The host system of any of aspects 16 through 18, where the one or more controllers are operable to receive the combination of signals in accordance with monitoring the plurality of pins during a first duration and to output the indication of the set of voltage levels during a second duration.
Aspect 20: The host system of any of aspects 16 through 19, where the combination of signals indicates an updated setting for a voltage level of the set of voltage levels.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
a controller mounted to a substrate;
one or more memory devices mounted to the substrate and coupled with the controller;
a first interface of the substrate comprising a first power supply input, a second power supply input, and a third power supply input, wherein the first power supply input and the second power supply input are coupled with the one or more memory devices and provide power for one or more first components and one or more second components of the one or more memory devices at a first voltage level and a second voltage level, respectively, and wherein the third power supply input is coupled with the controller and provides power for one or more components of the controller at a third voltage level; and
a second interface of the substrate comprising a plurality of pins configured to be coupled with a corresponding interface of a host system, the plurality of pins configured to output a fixed combination of signals indicating a set of voltage levels of a plurality of sets of voltage levels, wherein each of the plurality of sets of voltage levels comprises settings for the first voltage level, the second voltage level, and the third voltage level.

2. The memory system of claim 1, further comprising:
one or more resistors coupled with one or more pins of the plurality of pins, wherein the one or more resistors are coupled with at least one of the first power supply input the second power supply input, or a voltage regulator of the controller.

3. The memory system of claim 2, wherein the one or more pins output a first signal for the fixed combination of signals in accordance with being coupled with the one or more resistors.

4. The memory system of claim 2, wherein the one or more resistors are configured as pull-up circuits, as pull-down circuits, or as voltage divider circuits.

5. The memory system of claim 1, wherein:
at least one pin of the plurality of pins is decoupled from the first power supply input, the second power supply input, the third power supply input, and a ground, and
the at least one pin outputs a first signal for the fixed combination of signals in accordance with being decoupled.

6. The memory system of claim 1, wherein:
at least one pin of the plurality of pins is coupled with ground, and
the at least one pin outputs a second signal for the fixed combination of signals in accordance with being coupled with ground.

7. The memory system of claim 1, wherein the fixed combination of signals indicates an updated setting for the third voltage level.

8. The memory system of claim 1, wherein the third voltage level is less than the first voltage level and the second voltage level.

9. A memory system, comprising:
a controller mounted to a substrate;
one or more memory devices mounted to the substrate and coupled with the controller;
a first interface of the substrate comprising a first power supply input, a second power supply input, and a third power supply input, wherein the first power supply input and the second power supply input are coupled with the one or more memory devices and provide power for one or more first components and one or more second components of the one or more memory devices at a first voltage level and a second voltage level, respectively, and wherein the third power supply input is coupled with the controller and provides power for one or more components of the controller at a third voltage level; and
a second interface of the substrate comprising a plurality of pins configured to be coupled with an interface of a host system and with the controller, the controller operable to configure the plurality of pins to output a selected combination of signals indicating a set of voltage levels of a plurality of sets of voltage levels, wherein each of the plurality of sets of voltage levels comprises settings for the first voltage level, the second voltage level, and the third voltage level.

10. The memory system of claim 9, further comprising:
a plurality of switches of the controller that are coupled with the plurality of pins, wherein the controller is operable to configure each pin of the plurality of pins to output a first signal or a second signal for the selected combination of signals in accordance with switching a respective switch of the plurality of switches.

11. The memory system of claim 9, further comprising:
one or more resistors of the controller that are coupled with one or more pins of the plurality of pins, wherein the one or more resistors are coupled with a voltage regulator of the controller.

12. The memory system of claim 11, wherein the one or more resistors are configured as pull-up circuits, as pull-down circuits, or as voltage divider circuits.

13. The memory system of claim 9, further comprising:
a voltage regulator of the controller that is configured to provide power for the one or more components of the controller from the first power supply input or the second power supply input,
wherein the controller is operable to:
couple the one or more components with the voltage regulator for a first time period;
decouple the one or more components from the voltage regulator for a second time period subsequent to the first time period; and
couple the one or more components with the third power supply input for the second time period.

14. The memory system of claim 9, wherein the selected combination of signals indicates an updated setting for the third voltage level.

15. The memory system of claim 9, wherein the third voltage level is less than the first voltage level and the second voltage level.

16. A host system, comprising:
one or more controllers;
a first interface coupled with a power supply and the one or more controllers; and
a second interface comprising a plurality of pins coupled with an interface of a substrate of a memory system and with the one or more controllers, the one or more controllers configured to receive a combination of signals indicating a set of voltage levels of a plurality of sets of voltage levels via the plurality of pins, wherein the one or more controllers are operable to output an indication of the set of voltage levels to the power supply via the first interface, wherein each of the plurality of sets of voltage levels comprises settings for a first voltage level, a second voltage level, and a third voltage level.

17. The host system of claim 16, further comprising:
one or more resistors coupled with one or more pins of the plurality of pins, wherein the one or more resistors are coupled with a power supply input of the first interface or with a voltage regulator of the host system.

18. The host system of claim 16, wherein the one or more controllers are operable to determine the set of voltage levels of the plurality of sets of voltage levels in response to the combination of signals.

19. The host system of claim 16, wherein the one or more controllers are operable to receive the combination of signals in accordance with monitoring the plurality of pins during a first duration and to output the indication of the set of voltage levels during a second duration.

20. The host system of claim 16, wherein the combination of signals indicates an updated setting for a voltage level of the set of voltage levels.
